(19) United States
(12) Patent Application Publication
(10) Pub. No.: US 2009/0020870 A1
(43) Pub. Date: Jan. 22, 2009

(54) ELECTRONIC DEVICE PROVIDED WITH WIRING BOARD, METHOD FOR MANUFACTURING SUCH ELECTRONIC DEVICE AND WIRING BOARD FOR SUCH ELECTRONIC DEVICE

(76) Inventors: Shinji Watanabe, Tokyo (JP); Yukio Yamaguti, Tokyo (JP)

Correspondence Address: SUGHRUE MION, PLLC, 2100 PENNSYLVANIA AVENUE, N.W., SUITE 800, WASHINGTON, DC, 20037, US

(21) Appl. No.: 11/908,460

(22) PCT Filed: Mar. 14, 2006
(86) PCT No.: PCT/JP2006/304974

§ 371 Date: Sep. 12, 2007

(30) Foreign Application Priority Data
Apr. 5, 2005 (JP) 2005-108823

(51) Int. Cl. H01L 23/485; H01L 21/60; H05K 1/02

(52) U.S. Cl. 257/737; 438/106; 174/258; 257/E21.511; 257/E23.019

(57) ABSTRACT

An electronic device (1) is provided with a wiring board (2) and a semiconductor chip (5). The wiring board (2) is provided with a first resin layer (3a) and a second resin layer (3b) stacked one over another by having a wiring (4) in between. The semiconductor chip (5) has bumps (6) on one side and is connected with the wiring (4) by entering into the first resin layer (3a) to bring the bumps (6) into contact with the wiring (4). The first resin layer (3a) includes a thermoplastic resin, and the second resin layer (3b) has an elasticity of 1 GPa or higher at a melting point of the first resin layer (3a).

### TECHNICAL FIELD

The present invention relates to an electronic device, a method of manufacturing an electronic device, and a wiring board for use in an electronic device, and more particularly to an electronic device or the like which includes a wiring board and a semiconductor chip mounted on the wiring board by flip-chip mounting.

### BACKGROUND ART

One important task to be accomplished by connected structures of semiconductor chips and wiring boards according to flip-chip mounting is to increase the reliability of the joint between the semiconductor chip and the wiring board. Heretofore, there are known methods for fixing a semiconductor chip and a wiring board to each other with resin in order to increase the reliability of the joint.

One example of a method of fixing a semiconductor chip and a wiring board to each other with a resin is disclosed in JP-A No. 4-82241 (Patent Document 1). According to the method disclosed in Patent Document 1, a wiring board with interconnections disposed thereon is coated with an ultraviolet-curable or thermosetting adhesive resin, and a semiconductor chip with protrusive electrodes is pressed against the wiring board to bring the interconnections into contact with the protrusive electrodes. While the interconnections are being held in contact with the protrusive electrodes, the adhesive resin is cured to secure the semiconductor chip to the wiring board.

The above method is generally referred to as a pressure bonding process. According to the pressure bonding process, resin is supplied by an air-operated dispenser. A semiconductor chip has its upper surface attracted to and held by a mounting tool, and is positionally aligned with a wiring board. Thereafter, the semiconductor chip is pressed against the wiring board. In the pressure bonding process, the interconnections and the protrusive electrodes are brought into contact with each other while the resin is in a liquid phase, and the resin is cured while the interconnections and the protrusive electrodes are being kept in contact with each other. Therefore, any residual stresses produced in the joint between the wiring board and the semiconductor chip is small, and the joint is highly reliable.

In recent years, there have been a growing demand for low-profile semiconductor devices for use in mobile terminal units. To meet such demands, semiconductor chips are becoming lower in profile. However, as semiconductor chips are becoming lower in profile, the following problems arise: When the semiconductor chip attracted to and held by the mounting tool is pressed against the wiring board, the liquid resin is squeezed out around the edge of the semiconductor chip. The squeezed-out resin rises along the side surface of the semiconductor chip due to surface tension. When the rising resin reaches the upper surface of the semiconductor chip, it contacts the mounting tool. Since the resin is cured when it comes into contact with the mounting tool, the cured resin is bonded to the mounting tool, as a result of which the subsequent mounting process cannot be performed.

To prevent the resin from coming into contact with the mounting tool, the area of the surface of the mounting tool which contacts the semiconductor chip with respect to the area of the semiconductor chip is sufficiently reduced to allow the mounting tool to hold only the central region of the semiconductor chip. If the thickness of the semiconductor chip is small, however, then when the semiconductor chip is pressed, the central region of the semiconductor chip undergoes local stress which tends to break the semiconductor chip.

Because the thickness of the semiconductor chip is small, the resin can easily reach the upper surface of the semiconductor chip, so that variations in the supplied amount of the resin need to be minimized. Generally, it is known that if the thickness of the semiconductor chip is reduced to 0.15 mm or less, then the amount of the resin in a liquid phase is difficult to control.

A film-like resin material has been proposed in order to avoid the various above problems arising from using liquid resin. However, a film-like resin material for use as an underfill resin suffers drawbacks due to the film configuration, such as the adhesion of the film to the wiring board, the generation of air bubbles between the wiring board and the film, and joining reliability after the resin is cured. Furthermore, if a film-like resin material is used, the usual dispenser cannot be used, but a new film applicator has to be installed. Therefore, the use of a film-like resin material is problematic from the standpoint of manufacturing cost.

Another method of fixing a semiconductor chip and a wiring board to each other with resin is disclosed in JP-A No. 2001-156110 (Patent Document 2). According to the method disclosed in Patent Document 2, a thermoplastic resin coating is formed on a film board with interconnection disposed thereon in covering relation to the interconnections. Then, the thermoplastic resin coating is melted with heat, and the semiconductor chip is pressed against the thermoplastic resin coating while an ultrasonic energy is being applied thereto, thereby bringing the interconnections into contact with protrusive electrodes on the semiconductor chip. Thereafter, while the interconnections and the protrusive electrodes are being held in contact with each other, ultrasonic energy is continuously applied thereto to ultrasonically join the interconnections and the protrusive electrodes to each other. The thermoplastic resin coating is cooled and solidified to secure the semiconductor chip to the wiring board. Patent Document 2 states that the semiconductor chip is electrically and mechanically joined reliably to the wiring board according to the method.

It is known, however, that it is difficult to stably join all electrodes of a semiconductor chip having dimensions in which the length of each side exceeds 10 mm according to the ultrasonic joining method disclosed in Patent Document 2. Chip sizes to which the ultrasonic joining method is applicable are limited. Electronic devices generally employ Cu interconnections in view of connection reliability and electric characteristics. For making more reliable connections, the interconnections need to be electrolytically plated with nickel or gold.

Consequently, it is necessary that leads for plating are connected to all the interconnections. As the number of electrodes of a semiconductor chip which are connected to a wiring board increases, the number of leads for plating also increases. Many semiconductor chips have several hundreds of electrodes, and it is extremely difficult to lay out leads for plating for such semiconductor chips because of the limited interconnection space. These leads pose disadvantages with respect to electric characteristics because they operate as noise antennas. Therefore, the ultrasonic joining method is only used to connect small size semiconductor chips and have only several electrodes, such as those for data carrier applications. Many problems remain to be solved in applying the ultrasonic joining method to electronic devices that use semiconductor chips that are small in size and that have many electrodes.

It has been considered to press a semiconductor chip against a wiring board while a thermoplastic resin coating is being melted with heat to thereby connect the semiconductor chip to the interconnections, according to a method other than the ultrasonic joining method. According to this method, however, since the resin layer beneath the interconnections is greatly softened when the thermoplastic resin coating is heated, the interconnections sink into the lower resin layer when the semiconductor chip is pressed, which results in failure of the semiconductor chip and wiring board to sufficiently to connect each other.

### DISCLOSURE OF THE INVENTION

It is an object of the present invention to provide an electronic device which allows a wiring board and a chip component to be connected to each other with high reliability even if the chip component mounted on the wiring board is large in size and has many electrodes, and which can appropriately be reduced in size and thickness, and a method of manufacturing such an electronic device.

To achieve the above object, an electronic device according to the present invention comprises a wiring board and at least one chip component mounted on the wiring board. The wiring board includes a first resin layer and a second resin layer which are stacked one on the other with interconnections interposed therebetween. The chip component includes protrusive electrodes disposed on one surface thereof and is displaced into the first resin layer and connected to the interconnections with the protrusive electrodes being held in contact with the interconnections. The first resin layer contains at least one thermoplastic resin, and the second resin layer has an elastic modulus of 1 GPa or higher at the melting point of the first resin layer.

A method of manufacturing an electronic device with a chip component mounted on a wiring board according to the present invention comprising the steps of preparing a chip component with protrusive electrodes disposed on one surface thereof and a wiring board including a first resin layer and a second resin layer which are stacked one on the other with interconnections interposed therebetween, the first resin layer containing at least one thermoplastic resin, and the second resin layer having an elastic modulus of 1 GPa or higher at the melting point of the first resin layer, heating a region of the first resin layer in which the chip component is mounted to a temperature equal to or higher than the melting point of the first resin layer, pressing the chip component into the first resin layer in the heated region of the first resin layer while the surface with the protrusive electrodes is facing the first resin layer, bringing the protrusive electrode of the chip component into contact with the interconnections by piercing the first resin layer, and holding the protrusive electrodes and the interconnections in contact with each other until the first resin layer is cured. The first resin layer contains at least one thermoplastic resin, and the second resin layer has an elastic modulus of 1 GPa or higher at the melting point of the first resin layer.

A wiring board according to the present invention for mounting thereon at least one chip component with protrusive electrodes disposed on one surface thereof, comprises a first resin layer and a second resin layer stacked on the first resin layer with interconnections interposed therebetween, the protrusive electrodes of the chip component displaced into the first resin layer being held in contact with the interconnections. The first resin layer contains at least one thermoplastic resin, and the second resin layer has an elastic modulus of 1 GPa or higher at the melting point of the first resin layer. The chip component is displaced into the first resin layer with the protrusive electrodes being connected to the interconnections.

According to the present invention, the region of the first resin layer in which the chip component is mounted is heated to a temperature equal to higher than the melting point thereof, and then the chip component is displaced into the first resin layer to bring the protrusive electrodes into contact with the interconnections. At this time, since the elastic modulus of the second resin layer is 1 GPa or higher, the interconnections are prevented from sinking into the second layer while the chip component is being displaced into the first resin layer. The second resin layer thus functions as a chip component connection assisting layer for allowing the chip component to be displaced easily into the first resin layer while preventing the interconnections from sinking.

With the chip component displaced in the first resin layer, the first resin layer is cured while the protrusive electrodes and the interconnections are being held in contact with each other, thereby holding the chip electrode in the wiring board. During this time, as the temperature changes from a temperature equal to or higher than the melting point of the first resin layer to a temperature at which the first resin layer is cured, the chip component and second resin layer that are held in contact with the first resin layer change in dimensions. Their dimensions change because the chip component and the second resin layer have different coefficients of linear expansion. However, since the first resin layer which is melted or softened is present between the chip component and the second resin layer, stresses produced by the dimensional changes of the chip component and the second resin layer are relaxed by the first resin layer. The first resin layer thus functions as a chip component holding layer for holding the chip component as displaced and a stress relaxing layer for relaxing stresses generated between the chip component and the second resin layer. The protrusive electrodes of the chip component and the interconnections thus remain in contact with each other, with the result that the joint between the chip component and the wiring board has increased reliability.

When the chip component is displaced into the first resin layer, the first resin layer rises around the chip component. The height by which the first resin layer rises depends on the distance by which the chip component is displaced, or in other words, the thickness of the first resin layer. Generally, resin layers are made of a material in the form of a film. Since the thickness of the film can be controlled in real time by a film manufacturing apparatus, the thickness of the film material for use as resin layers is highly accurate. Therefore, the thickness of the first resin layer can be managed with high accuracy. Even if the thickness of the chip component is small, the thickness of the first resin layer can be managed by selecting an optimum film thickness depending on the thickness and size of the chip component and the amount of resin forced out by the displacement of the chip component into the first resin layer so that the first resin layer will not reach the surface of the chip component displaced into the first resin layer. Therefore, the resin of the first resin layer is easily prevented from sticking to a mounting tool by a highly simple process of managing the thickness of the first resin layer. As a consequence, the size of the mounting tool does not need to be smaller than the chip component to prevent the resin from sticking to the mounting tool. Because a mounting tool which is greater in size than the chip component can be used, the mounting tool does not apply local stresses to the chip component which is thin, and the chip component does not tend to be damaged when the chip component is displaced into the first resin layer.

According to the present invention, as described above, the reliability of the joint between the chip component and the wiring board is increased by appropriately setting the elastic moduli of the first and second resin layers of the wiring board. Because the chip component is directly connected to the interconnections in the wiring board, the interconnections are made simpler than those of electronic devices of the related art. The electronic device and various apparatus incorporating the electronic device are thus reduced in size and thickness.

### BRIEF DESCRIPTION OF THE DRAWINGS

FIG. 1 is a cross-sectional view of an electronic device according to an embodiment of the present invention;

FIG. 2 is a cross-sectional view of a wiring board used in the electronic device shown in FIG. 1;

FIG. 3 is a cross-sectional view of a semiconductor chip used in the electronic device shown in FIG. 1;

FIG. 4 is a view illustrative of a method of forming bumps on the semiconductor chip;

FIG. 5 is a view illustrative of another method of forming bumps on the semiconductor chip;

FIG. 6 is a graph showing the relationship between the temperature and the elastic modulus of crystalline resin and noncrystalline resin;

FIG. 7 is a cross-sectional view of another electronic device to which the present invention is applied;

FIG. 8 is a cross-sectional view of still another electronic device to which the present invention is applied;

FIG. 9 is a cross-sectional view of yet another electronic device to which the present invention is applied;

FIG. 10 is a cross-sectional view of yet still another electronic device to which the present invention is applied;

FIG. 11 is a cross-sectional view of a further electronic device to which the present invention is applied;

FIG. 12 is a cross-sectional view of a yet further electronic device to which the present invention is applied;

FIG. 13 is a cross-sectional view of a yet still further electronic device to which the present invention is applied;

FIG. 14 is a cross-sectional view of another electronic device to which the present invention is applied;

FIG. 15 is a cross-sectional view of still another electronic device to which the present invention is applied;

FIG. 16 is a cross-sectional view of yet another electronic device to which the present invention is applied;

FIG. 17 is a cross-sectional view of yet still another electronic device to which the present invention is applied;

FIG. 18 is a cross-sectional view of a further electronic device to which the present invention is applied;

FIG. 19A is a plan view of a wiring board for use in another electronic device to which the present invention is applied;

FIG. 19B is a cross-sectional view of an electronic device having two semiconductor chips mounted parallel to each other on the wiring board shown in FIG. 19A;

FIG. 20 is a cross-sectional view of still another electronic device to which the present invention is applied;

FIG. 21A is a plan view of another wiring board according to the present invention;

FIG. 21B is a cross-sectional view of a semiconductor package having two superposed semiconductor chips mounted on the wiring board shown in FIG. 21A;

FIG. 22 is a schematic cross-sectional view of a functional module to which the present invention is applied;

FIG. 23 is a schematic cross-sectional view of a functional module to which an arrangement of the related art is applied; and

FIG. 24 is a cross-sectional view illustrative of problems which arise if a second resin layer does not satisfy a condition based on the present invention.

### DESCRIPTION OF REFERENCE CHARACTERS

1 electronic device
2 wiring board
3a first resin layer
3b second resin layer
4, 4a, 4b interconnection
4g, 7 ground pattern
5 semiconductor chip
6 bump
8 via hole
9 solder resist

### BEST MODE FOR CARRYING OUT THE INVENTION

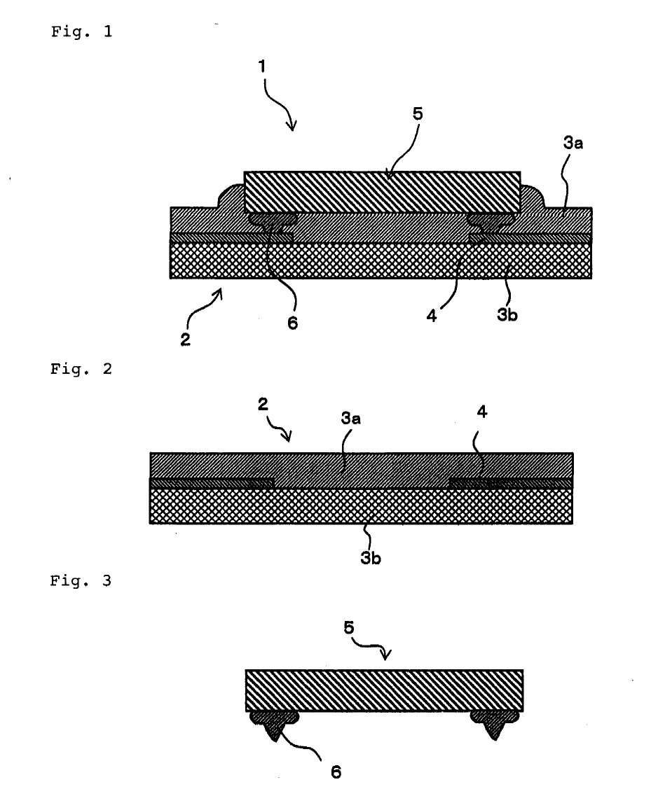

FIG. 1 shows electric device 1 including wiring board 2 and semiconductor chip 5, according to an embodiment of the present invention.

As shown in FIG. 2, wiring board 2 comprises first resin layer 3a and second resin board 3b. A certain pattern of interconnections 4 is formed on second resin board 3b. First resin layer 3a is stacked on the surface of second resin board 3b on which interconnections 4 are disposed. Interconnections 4 can be formed by a subtractive process that is generally used to form interconnections on a board. However, interconnections 4 may be formed by another process such as an additive process or a semi-additive process. Interconnections 4 are typically made of copper. However, in a region where interconnections 4 are electrically connected to external terminals (not shown) of the semiconductor chip, interconnections 4 may be made of a less oxidizable material such as Au or the like for higher reliability.

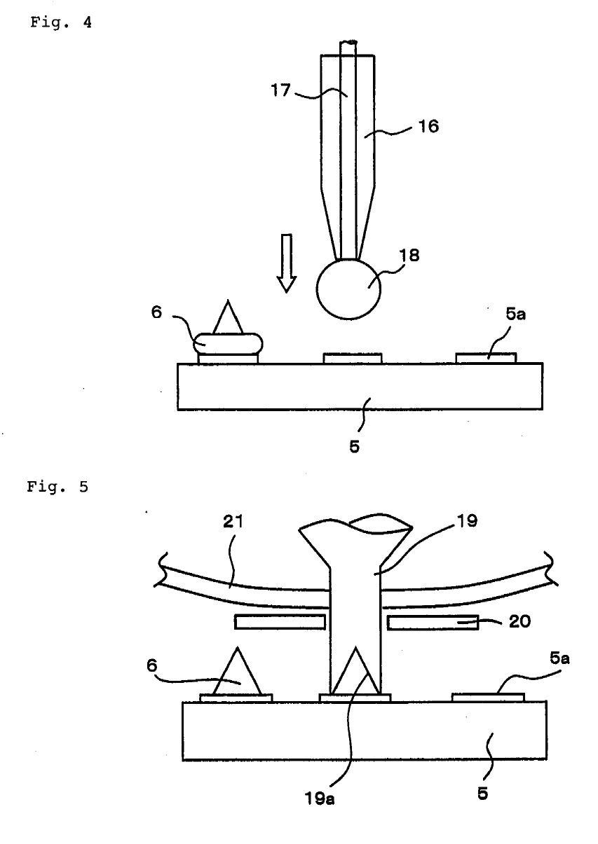

FIG. 3 shows semiconductor chip 5 used in electronic device 1 shown in FIG. 1. Semiconductor chip 5 has a circuit surface on one side thereof. Electrode pads (not shown in FIG. 3) that are connected to an internal circuit of semiconductor chip 5 are disposed on the circuit surface. Bumps 6 with pointed ends that are formed as external terminals are disposed on the electrode pads. Bumps 6 may be formed by wiring bonding or punching.

A method of forming bumps 6 according to wire bonding will be described below with reference to FIG. 4. First, gold ball 18 is formed on the tip end of gold wire 17 gripped by capillary 16. Gold ball 18 is pressed against electrode pad 5a on the circuit surface of semiconductor chip 5 by capillary 16. After gold ball 18 is joined to electrode pad 5a, gold wire 17 is torn apart to form bump 6 having a pointed end. Gold ball 18 is formed by having gold wire 17 that projects from the tip end of capillary 16, applying a high voltage between a torch and gold wire 17 to produce a spark therebetween to melt the portion of gold wire 17 which projects from the tip end of capillary 16, and allowing the melted portion of gold wire 17 to be shaped into a ball under surface tension when the melted portion is solidified.

Bumps 6 are formed by punching as follows: As shown in FIG. 5, ribbon material 21 is punched by punch 19 having conical recess 19a and die 20, and the punched portion is joined to pad 5a on the circuit surface of semiconductor chip 5, thereby forming bump 6 having a pointed end.

As shown in FIG. 1, bump 6 pierces first resin layer 3a to come into contact with interconnection 4 when semiconductor chip 5 is pressed (displaced) into first resin layer 3a. As described in detail later, when semiconductor chip 5 is pressed into first resin layer 3a, the end of bump 6 may not necessarily be pointed because the elastic modulus of first resin layer 3a is sufficiently small. However, it is preferable for bump 6 to have a pointed end because it can easily pierce first resin layer 3a and it can achieve joining reliability. Bumps 6 may comprise various bumps such as high-temperature solder bumps, copper bumps, gold bumps, etc., and suffer no limitations whatsoever.

Referring back to FIG. 1, semiconductor chip 5 has its side where bumps 6 are mounted, displaced into first resin layer 3a, with bumps 6 that pierces first resin layer 3a and is connected to interconnections 4. Furthermore, semiconductor chip 5 is held by first resin layer 3a. To produce this structure, resin layers 3a, 3b of wiring board 2 are constructed as follows: First resin layer 3a includes at least one thermoplastic resin. At the melting point of first resin layer 3a, second resin layer 3b has an elastic modulus of 1 GPa or higher. The thickness of first resin layer 3a is smaller than the height of semiconductor chip 5 after it is mounted on wiring board 2 (after semiconductor chip 5 is mounted on wiring board 2, the tips of bumps 6 are crushed, and the height of semiconductor chip 5 is smaller than before it is mounted on wiring board 2. The surface of semiconductor chip 5 projects from the surface of first resin layer 3a.

A method of mounting semiconductor chip 5 on wiring board 2 according to the present embodiment will be described below.

Before semiconductor chip 5 is mounted on wiring board 2, the surface of first resin layer 3a should desirably be activated by plasma processing or ultraviolet irradiation in order to increase the adhesion of first resin layer 3a to semiconductor chip 5.

For mounting semiconductor chip 5 on wiring board 2, wiring board 2 and semiconductor chip 5 are positionally aligned with each other. Wiring board 2 and semiconductor chip 5 may be positionally aligned with each other by positionally aligning semiconductor chip 5, that is attracted to and held by the mounting tool of a mounting apparatus, with positioning marks on wiring board 2. The positioning marks should desirably be provided on interconnections 4 to which bumps 6 are to be connected. Generally, the positioning marks are formed at the same time that interconnections 4 are formed. If first resin layer 3a is not transparent, then in order to allow the positioning marks to be recognized from the surface of wiring board 2, openings are formed in the portions of first resin layer 3a which correspond to the positioning marks by laser beam machining or photoetching. Alternatively, if first resin layer 3a and second resin layer 3b are bonded into wiring board 2, then through holes may be formed in the portions of first resin layer 3a which correspond to the positioning marks by punching or the like.

Then, semiconductor chip 5 that is attracted to and held by the mounting tool is displaced into first resin layer 3a of wiring board 2. The mounting tool is of a structure which is capable of heating and pressing semiconductor chip 5. While the mounting tool is heating semiconductor chip 5 that is attracted thereto and held thereby to a temperature equal to or higher than the melting point of first resin layer 3a, the mounting tool presses semiconductor chip 5 against first resin layer 3a of wiring board 2 that has been positioned with respect to semiconductor chip 5. Since semiconductor chip 5 that is heated is pressed against first resin layer 3a, the heat of semiconductor chip 5 is transferred to first resin layer 3a, so that first resin layer 3a is melted in its region held in contact with semiconductor chip 5 and a surrounding region thereof. Semiconductor chip 5 is easily displaced into first resin layer 3a while melting first resin layer 3a around semiconductor chip 5.

As semiconductor chip 5 is further displaced into first resin layer 3a, bumps 6 pierce first resin layer 3a and they are finally connected to interconnections 4. During the process in which bumps 6 pierce first resin layer 3a and are connected to interconnections 4, second resin layer 3b has a sufficiently high elastic modulus, and is not essentially deformed by semiconductor chip 5 that is pressed against first resin layer 3a. Therefore, any sinking of interconnections 4 into second resin layer 3b is greatly reduced, and interconnections 4 and bumps 6 are firmly held in close contact with each other.

Finally, while interconnections 4 and bumps 6 are being held in close contact with each other, wiring board 2 and semiconductor chip 5 are cooled until first resin layer 3a is cured. Wiring board 2 and semiconductor chip 5 may be cooled naturally or forcibly. Wiring board 2 and semiconductor chip 5 may be cooled to the room temperature because only first resin layer 3a needs to be cured.

In the above process, in order to transfer the heat applied to semiconductor chip 5 efficiently to wiring board 2, it is desirable to heat a stage by which wiring board 2 is held when semiconductor chip 5 is displaced into first resin layer 3a. However, if second resin layer 3b is also made of a thermoplastic resin, the pressure under which bumps 6 and interconnections 4 are held in contact with each other may not be sufficient if second resin layer 3b is excessively softened. Therefore, the temperature of the stage by which wiring board 2 is held should preferably be lower than the temperature of the mounting tool that holds semiconductor chip 5. For example, the temperature of the mounting tool is selected in a range from 200 to 350° C. and the temperature of the stage is selected in a range from 50° C. to 200° C. which is lower than the temperature of the mounting tool.

Since bumps 6 have pointed ends, bumps 6 are displaced into first resin layer 3a while pushing first resin layer 3a away and have their pointed ends deformed when pressed against interconnections 4. Therefore, bumps 6 that have pointed ends provide higher joining reliability. When semiconductor chip 5 is embedded to a desired depth in first resin layer 3a and the joining of bumps 6 to interconnections 4 is completed, heating of the mounting tool is finished. It can be determined whether bumps 6 are joined to interconnections 4 by measuring the load applied from semiconductor chip 5 to the mounting tool when semiconductor chip 5 is pressed. Since the load and the degree by which bumps 6 are crushed are correlated to each other, the degree by which bumps 6 are crushed, i.e., the joined state of bumps 6 and interconnections 4, is known from the load applied to the mounting tool. Thereafter, as the temperature of semiconductor chip 5 is lowered, first resin layer 3a is sufficiently cured. After semiconductor chip 5 is continuously pressed by the mounting tool until first resin layer 3a gains an elastic modulus capable of keeping bumps 6 and interconnections 4 in contact with each other, the mounting tool is elevated.

Since the surfaces of interconnections 4 to which bumps 6 are connected have already been covered with first resin layer 3a, they are prevented from oxidation and contamination during the manufacturing process. Bumps 6 and interconnections 4 may be connected by metal diffusion joining or may remain connected by being held in contact with each other by the insulating resin.

As described above, since first resin layer 3a is made of a resin including a thermoplastic resin and second resin layer 3b of a resin having an elastic modulus of 1 GPa or higher at the melting point of first resin layer 3a, wiring board 4 and semiconductor chip 5 can be easily connected to each other by displacing semiconductor chip 5 into first resin layer 3a while first resin layer 3a is being melted with heat and by holding bumps 6 of semiconductor chip 5 in close contact with interconnections 4.

When first resin layer 3a is thereafter cured, semiconductor chip 5 is embedded in and held by wiring board 4. Consequently, wiring board 4 and semiconductor chip 5 remain firmly connected to each other. While semiconductor chip 5 is being displaced into first resin layer 3a, second resin layer 3b has a sufficient elastic modulus. Accordingly, any sinking of interconnections 4 into second resin layer 3b is greatly reduced when semiconductor chip 5 is pressed, and interconnections 4 and bumps 6 are held in highly close contact with each other.

The insulating layers of the wiring board may be made of an inorganic material such as glass, ceramics, or the like rather than a resin. Such an inorganic material may be used instead of second resin layer 3b to reduce sinking of interconnections 4. However, because such an inorganic material is brittle and easily breakable, it cannot easily be handled in the manufacturing process. According to the present embodiment, since any of the insulating layers are mainly made of a resin, their handleability is not lowered. As one form of the electronic device according to the present embodiment, the electronic device may be constructed as a BGA device and may be mounted on another board such as a motherboard or the like. If second resin layer 3b is made of an inorganic material in such an application, then since its linear expansion coefficient is greatly different from the linear expansion coefficient of the other board, joining reliability cannot be achieved. According to the present invention, since any of the insulating layers are mainly made of a resin, their linear expansion coefficient is substantially the same as the linear expansion coefficient of the other board, and joining reliability can be achieved.

The above features have no bearing on the planar size and the number of electrodes of semiconductor chip 5. Therefore, the above structure and method are applicable to a wide range of semiconductor chips 5, wherein the length of each side ranges from several mm to more than 10 mm, as they are mounted on wiring board 2.

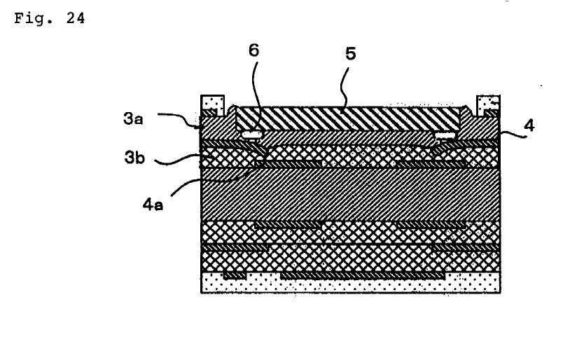

FIG. 24 is a cross-sectional view showing a case in which the above condition is not satisfied by the elastic modulus of second resin layer 3b, i.e., the elastic modulus is less than 1 GPa at the melting point of first resin layer 3a. As shown in FIG. 4, if second resin layer 3b does not satisfy the above condition, forces that are produced when semiconductor chip 5 is pressed are applied to interconnections 4, causing interconnections 4 to sink substantially into the resin largely. As a result, sufficient pressure is not achieved to hold bumps 6 and interconnections 4 in contact with each other, and the distance between interconnections 4 connected to bumps 6 and lower layer of interconnections 4a is reduced, tending to cause an insulation failure between interconnections 4, 4a or a short circuit therebetween. Furthermore, since semiconductor chip 5 itself sinks substantially into wiring board 2, first resin layer 3b rises substantially and possibly come into contact with the mounting tool.

The types and properties of resins that can be used as first resin layer 3a and second resin layer 3b will be described below.

First resin layer 3a needs to contain a thermoplastic resin so that it can be melted when semiconductor chip 5 is mounted on wiring board 2 and semiconductor chip 5 can be pressed. First resin layer 3a may contain a thermosetting resin and other additives insofar as it can be melted and this allows semiconductor chip 5 to be pressed.

Second resin layer 3b needs to have an elastic modulus of 1 GPa or higher at the melting point of first resin layer 3a. Insofar as second resin layer 3b satisfies this condition, then it may be made of either a thermoplastic resin or a thermosetting resin. Furthermore, second resin layer 3b may be made of a hybrid material including a combination of a thermoplastic resin and a thermosetting resin. Since second resin layer 3b may be made not only of a thermoplastic resin but also of a thermosetting resin, a greater choice of materials is available.

Thermoplastic resins are roughly classified into crystalline resins where a polymer chain is regularly arranged in a temperature range lower than the melting point and noncrystalline resins where a polymer chain is not regularly arranged below the melting point.

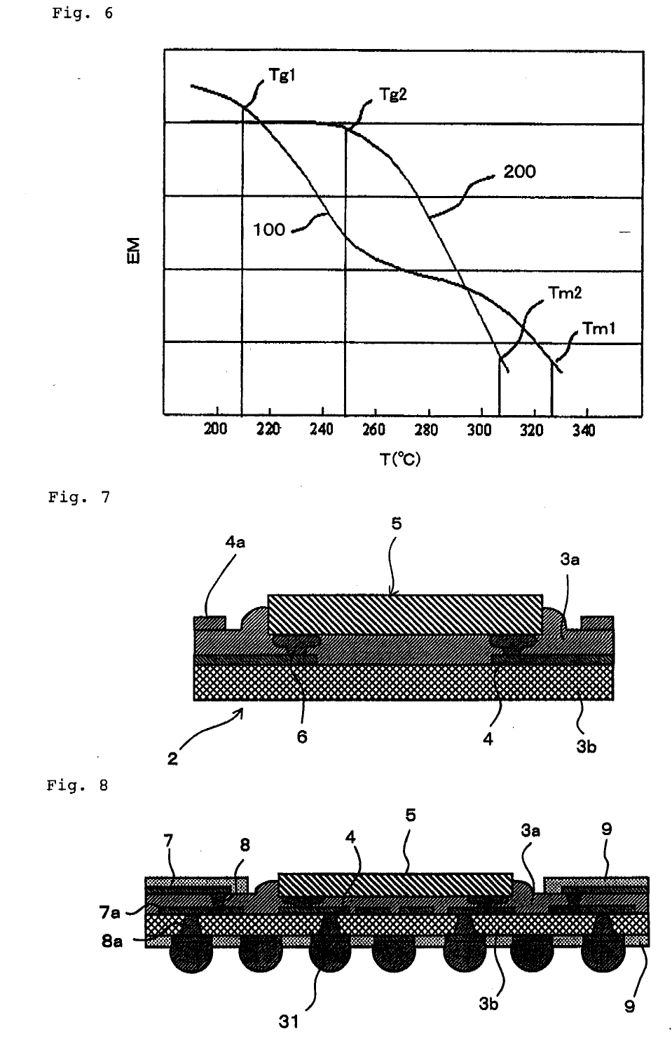

FIG. 6 is a graph showing the relationship between the temperature (T) and the elastic modulus (EM) of a crystalline resin and a noncrystalline resin. In FIG. 6, the crystalline resin has elastic modulus curve 100, and the noncrystalline resin has elastic modulus curve 200. Tg1 and Tm1 on elastic modulus curve 100 represent the glass transition point and melting point of the crystalline resin. Similarly, Tg2 and Tm2 on elastic modulus curve 200 represent the glass transition point and melting point of the noncrystalline resin. Specific values of the elastic modulus are omitted from the illustration in FIG. 6 as FIG. 6 is used to indicate the tendency of the elastic modulus which varies as the temperature varies.

It can be seen from the graph that the elastic modulus of the crystalline resin gradually decreases when the temperature rises. On the other hand, the elastic modulus of the noncrystalline resin is essentially constant up to the glass transition point (Tg) and sharply drops at temperatures higher than the glass transition point.

According to the present invention wherein bumps 6 and interconnections 4 are held in contact with each other by first resin layer 3a, the crystalline resin is applicable to an electronic device which is essentially free of a thermal load in the process after semiconductor chip 5 is mounted. However, if an electronic device undergoes a thermal load due to reflow after semiconductor chip 5 is mounted, then a noncrystalline thermoplastic resin whose elastic modulus falls to a small degree in the reflow temperature range is suitable for use in such an electronic device. Under an environmental load such as in a temperature cycle, a noncrystalline resin whose elastic modulus can be maintained up to a relatively high temperature can achieve joining reliability.

If a crystalline resin and a noncrystalline resin have the same heat resistance, then the melting point of the noncrystalline resin is lower than the melting point of the crystalline resin. Therefore, as the mounting temperature can be lowered at the time the bumps pierce the first resin layer, the noncrystalline resin is more advantageous from the standpoint of the manufacturing process, In particular, if the resin of first resin layer 3a is required to be resistant to reflowing heat, the resin should preferably be a material which has a melting point in the range from 240 to 300° C. and which is rigid enough to hold bumps 6 and interconnections 4 that are connected to each other in a reflow temperature range from 190 to 220° C. If the resin of first resin layer 3a is not required to be resistant to reflowing heat, then the resin should preferably be a material which has a melting point in the range from 100° C. to 250° C.

If a crystalline resin and a noncrystalline resin are combined into a composite material, then such a composite material can exhibit a noncrystalline property in which the reduction in the elastic modulus is small up to the glass transition point. Therefore, the composite material is free of the above shortcomings of crystalline resin.

The crystalline resin may comprise PK (polyketone), PEEK (polyetheretherketone), LCP (liquid crystal polymer), PPA (polyphthal amide), PPS (polyphenylene sulfide), PCT (polydicyclohexylene dimethylene terephthalate), PBT (polybutylene terephthalate), PET (polyethylene terephthalate), POM (polyacetal), PA (polyamide), PE (polyethylene), PP (polypropylene), or the like. The noncrystalline resin may comprise PBI (polybenzoimidazole), PAI (polyamideimide), PI (polyimide), PES (polyethersulfone), PEI (polyetherimide), PAR (polyarylate), PSF (polysulfone), PC (polycarbonate), altered PPE (polypheninether), PPO (polyphenylene oxide), ABS (acrylonitrile butadiene styrene), PMMA (polymethyl methacrylate), PVC (polyvinyl chloride), PS (polystyrene), AS (acrylonitrile styrene), or the like.

One important element to be taken into account when selecting the materials of first resin layer 3a and second resin layer 3b is the linear expansion coefficient in addition to the crystalline resin/noncrystalline resin. With respect to the reliability of semiconductor chip 5 after it is mounted, particularly an environmental load such as in a temperature cycle, if the linear expansion coefficient in the Z direction (thickness-wise direction) is large, then this is unfavorable for keeping bumps 6 and interconnections 4 in contact with each other. There is a process for adjusting the linear expansion coefficient by mixing the resin with a filler (fine particles) having a low linear expansion coefficient, According to this process, the linear expansion coefficient can be adjusted not only in the Z direction, but also in the XY directions (in-plane directions), thereby providing great advantages relatively easily. Some resins, like LCP, can have the linear expansion coefficient set to a desired value by controlling the crystalline orientation. However, LCP is disadvantageous in that though the linear expansion coefficient can be easily adjusted in the XY directions, it is difficult to adjust in the Z direction. However, LCP is applicable to the present invention if the adjustment of the linear expansion coefficient in the XY directions is sufficient.

First resin layer 3a should preferably have its linear expansion coefficient in a range between the linear expansion coefficient of semiconductor chip 5 and the linear expansion coefficient of second resin layer 3b for keeping the joint with semiconductor chip 5 and bumps 6 reliable against temperature changes. More preferably, the linear expansion coefficient of first resin layer 3a is closer to the linear expansion coefficient of semiconductor chip 5 than an intermediate value between the linear expansion coefficient of semiconductor chip 5 and the linear expansion coefficient of second resin layer 3b. Therefore, it is preferable to lower the linear expansion coefficient to 5 ppm/° C. to 60 ppm/° C. by including a material having a low linear expansion coefficient, such as a silica filler, in first resin layer 3a.

However, it is possible to reduce the effect of the linear expansion coefficient in the Z direction by holding the joint between bumps 6 and interconnections 4 compressed under the pressure applied to displace semiconductor chip 5 into first resin layer 3a and also by reducing the distance between semiconductor chip 5 and interconnections 4 to about 50 μm or less to reduce the absolute value of a temperature-dependent dimensional change of first resin layer 3a in the Z direction. According to the present invention, therefore, the linear expansion coefficient of first resin layer 3a may not necessarily be limited to a value smaller than the linear expansion coefficient of second resin layer 3b. Conversely, even if the linear expansion coefficient of first resin layer 3a is higher than the linear expansion coefficient of second resin layer 3b, second resin layer 3b may be made of a highly rigid, low-expansion material such as a general glass epoxy material in the form of a glass cloth impregnated with a resin, for thereby reducing expansion of first resin layer 3a, so that a reduction in the joining reliability due to the difference between the coefficients of linear expansion can be prevented from occurring. The linear expansion coefficient of first resin layer 3a has its optimum value variable depending on the chip size of semiconductor chip 5 mounted thereon, the bump pitch, the number of bumps, and the thickness of wiring board 2. However, if semiconductor chip 5 has a chip size of 10 mm□10 mm, for example, then the linear expansion coefficient of first resin layer 3a is roughly indicated as 60 ppm/° C. or less in the XY directions and 80 ppm/° C. or less in the Z direction.

The thermosetting resin added to first resin layer 3a and the thermosetting resin of at least a portion of second resin layer 3b may be bisphenol A epoxy resin, dicyclopentadiene epoxy resin, cresol novolac epoxy resin, biphenyl epoxy rein, naphthalene epoxy resin, resol phenolic resin, novolac phenolic resin, or the like, or a composite resin material of some of these resins.

Specific examples of electronic devices fabricated by combining the above resins as the materials of first resin layer 3a and second resin layer 3b will be described below.

### COMBINATION EXAMPLE 1

According to the present example, first resin layer 3a was made of PEI which is a noncrystalline thermoplastic resin having a melting point of 250° C., and second resin layer 3b was made of LCP which is a crystalline thermoplastic resin having a melting point of 350° C. Semiconductor chip 5 was mounted on wiring board 2 constructed of such first resin layer 3a and second resin layer 3b according to the above procedure. LCP of second resin layer 3b was prepared in two types, one having an elastic modulus of 0.7 GPa and the other having an elastic modulus of 1.0 GPa at a temperature of 250° C. near the melting point of PEI.

Wiring board 2 and semiconductor chip 5 that were used had the following major dimensions: Each of first resin layer 3a and second resin layer 3b of wiring board 2 was in the form of a film having a thickness of 50 μm. Second resin layer 3b was of a six-layer structure, and first resin layer 3a in the form of a single layer was disposed on second resin layer 3b, so that first and second layers 3a, 3b are jointly of a seven-layer structure. Interconnections 4 were produced by plating a copper pattern with an Ni layer having a thickness in the range from 3 to 5 μm and a gold layer having a thickness in the range from 0.5 to 1.0 μm. Interconnections 4 had a total thickness of about 20 μm. Interconnections 4 were provided between resin layers 3a, 3b and on both surfaces of the wiring board so that interconnections 4 were provided as eight layers in the overall wiring board. The total thickness of finished wiring board 2 including resin layers 3a, 3b and interconnections 4 was 400 μm. Since resin layers 3a, 3b are partly embedded between interconnections 4 when the assembly is pressed, the total thickness of finished wiring board 2 differs depending on the density of interconnections 4. Semiconductor chip 5 had planar dimensions of 10 mm×10 mm, a thickness of 0.3 mm, and 480 bumps 6 each having a height of about 57 μm.

The mounting tool used to mount semiconductor chip 5 on wiring board 2 had a temperature of 300° C. when pressing semiconductor chip 5 into wiring board 2. After bumps 6 of semiconductor chip 5 come into contact with interconnections 4, the heating of the mounting tool was stopped. At the time the temperature of the mounting tool reached 200° C., the mounting tool was lifted off semiconductor chip 5.

Semiconductor chip 5 was mounted on wiring board 2 under the above temperature conditions, and the connection between bumps 6 and interconnections 4 was confirmed. If second resin layer 3b was made of LCP having an elastic modulus of 0.7 GPa at 250° C., then many conduction failures occurred due to insufficient pressure under which bumps 6 and interconnections 4 were held in contact with each other. A microscopic observation of the cross section of the area of contact between bumps 6 and interconnections 4 indicated that interconnections 4 greatly sank in the area of contact between bumps 6 and interconnections 4. If second resin layer 3b was made of LCP having an elastic modulus of 1.0 GPa at 250° C., then connections that sank into the resin layer to a smaller degree that interconnections 4 and an increased contact pressure of contact between bumps 6 and interconnections 4 were produced, and conduction failures between bumps 6 and interconnections 4 due to sinking of interconnections 4 did not occur. It can be determined whether the contact pressure between bumps 6 and interconnections 4 is high or low by measuring the conduction resistance between bumps 6 and interconnections 4. The higher the pressure contact, the lower is the conduction resistance, and the lower the contact pressure, the higher is the conduction resistance.

### COMBINATION EXAMPLE 2

According to the present example, first resin layer 3a was made of PEI used in combination example 2, and second resin layer 3b was made of “IBUKI” (registered trademark) which is a PEEK-based thermoplastic copper-clad film manufactured by Mitsubishi Plastics Inc. “IBUKI” employs a crystalline PEEK material as a base, and is combined with a noncrystalline resin to provide noncrystalline resin characteristics such that the elastic modulus is less liable to decrease at high temperatures. “IBUKI” has its linear expansion coefficient reduced by containing a filler. The PEEK material used as a base of “IBUKI” has high heat resistance since its melting point exceeds 300° C. PEI of first resin layer 3a has a melting point which is about 50° C. lower than the melting point of “IBUKI”. At the melting point of PEI, the elastic modulus of “IBUKI” is higher than 1 GPa.

Wiring board 2 and semiconductor chip 5 had major dimensions identical to those of combination example 1. The temperature conditions of the mounting tool were also identical to those of combination example 1.

According to the present example, sinking of interconnections 4 was small, keeping interconnections 4 and bumps 6 firmly joined to each other, and conduction failures between bumps 6 and interconnections 4 due to sinking of interconnections 4 did not occur.

### COMBINATION EXAMPLE 3

According to the present example, first resin layer 3a was made of “IBF-3021” manufactured by Sumitomo Bakelite Co., Ltd., which is a resin material including a thermoplastic resin as the main component with a trace amount of thermosetting resin being added thereto, and second resin layer 3b was made of LCP. “IBF-3021” is melted in a temperature range from 200° C. to 250° C. which is the mounting temperature range of “IBF-3021”, and the elastic modulus of LCP is higher than 1 GPa in this temperature range.

Wiring board 2 and semiconductor chip 5 had major dimensions identical to those of combination example 1. The mounting tool had a temperature of 250° C. when pressing semiconductor chip 5 into wiring board 2. After bumps 6 of semiconductor chip 5 came into contact with interconnections 4, the heating of the mounting tool was stopped. At the time that the temperature of the mounting tool reached 150° C., the mounting tool was lifted off semiconductor chip 5.

According to the present example, the sinking of interconnections 4 was small, keeping interconnections 4 and bumps 6 firmly joined to each other, and conduction failures between bumps 6 and interconnections 4 due to the sinking of interconnections 4 did not occur.

### COMBINATION EXAMPLE 4

According to the present example, first resin layer 3a was made of “IBF-3021” used in combination example 3, and second resin layer 3b was made of polyimide which is widely used as the material of flexible wiring boards. Polyimide is a noncrystalline thermoplastic resin. “IBF-3021” is melted in a temperature range from 200° C. to 250° C. which is the mounting temperature range of “IBF-3021”, and the elastic modulus of polyimide is higher than 1 GPa in this temperature range.

Wiring board 2 and semiconductor chip 5 had major dimensions as follows: First resin layer 3a had a thickness of 50 μm, second resin layer 3b had a thickness of 25 μm, and wiring board 2 had a total thickness of 75 μm. Interconnections 4 were produced by plating a copper pattern with an Ni layer having a thickness in the range from 3 to 5 μm and a gold layer having a thickness in the range from 0.5 to 1.0 μm. Interconnections 4 had a total thickness of about 20 μm. Semiconductor chip 5 had planar dimensions of 6 mm×8 mm, a thickness of 0.1 mm, and 64 bumps 6.

The mounting tool used to mount semiconductor chip 5 on wiring board 2 had a temperature of 250° C. when pressing semiconductor chip 5 into wiring board 2. After bumps 6 of semiconductor chip 5 came into contact with interconnections 4, the heating of the mounting tool was stopped. At the time the temperature of the mounting tool reached 150° C., the mounting tool was lifted off semiconductor chip 5.

According to the present example, interconnections 4 sank only to a small degree into the resin layer, which thereby ensured that interconnections 4 and bumps 6 were firmly joined to each other, and conduction failures between bumps 6 and interconnections 4 due to sinking of interconnections 4 did not occur.

Second resin layer 3b should preferably have an elastic modulus which is as high as possible in the temperature range of semiconductor chip 5 when it is mounted, i.e., in the vicinity of the melting point of first resin layer 3a. If second resin layer 3b is made of a thermoplastic resin, then it should preferably be a noncrystalline resin having a high elastic modulus up to near the melting point. There is available a limited range of crystalline resins whose elastic modulus is 1 GPa or higher at a high temperature of 250° C., for example. On the other hand, a greater choice of materials is available in many types for noncrystalline resins such as polyimide used in the present example.

Further advantages of the present invention will be described below.

While semiconductor chip 5 is being displaced into first resin layer 3a, the portion of first resin layer 3a which is held in contact with semiconductor chip 5 and a surrounding portion thereof are melted or softened by the heat, and are cured as the temperature subsequently drops. While the temperature is dropping, semiconductor chip 5 and second resin layer 3b shrink. Generally, the linear expansion coefficient of semiconductor chip 5 is smaller than the linear expansion coefficient of resins, so that the amount of shrinkage of semiconductor chip 5 and the amount of shrinkage of second resin layer 3b are different from each other. However, since first resin layer 3a that is present between semiconductor chip 5 and second resin layer 3b remains melted or softened while the temperature is dropping, stresses generated due to the difference between the amount of shrinkage of semiconductor chip 5 and the amount of shrinkage of second resin layer 3b are relaxed by first resin layer 3a.

When semiconductor chip 5 is displaced into first resin layer 3a, first resin layer 3a, as it is forced out by semiconductor chip 5, rises around semiconductor chip 5. As first resin layer 3a rises to high level, a portion of first resin layer 3a reaches the surface of semiconductor chip 5, and the resin of first resin layer 3a may possibly stick to the mounting tool, which tends to make the mounting tool useless. First resin layer 3a rises to a greater extent as semiconductor chip 5 is displaced more deeply into first resin layer 3a. In particular, if semiconductor chip 5 has a small thickness of 0.15 mm or less, for example, then the resin of first resin layer 3a sticks to the mounting tool even when first resin layer 3a rises slightly. First resin layer 3a not only serves as part of wiring board 2, but also serves to hold semiconductor chip 5 on wiring board 2. Therefore, if the thickness of first resin layer 3a is not sufficient, semiconductor chip 5 is not reliably secured in position.

First resin layer 3a which has a thickness of several tens [μm] is generally made of a material in the form of a film. Since the thickness of the film can be controlled in real time by a film manufacturing apparatus, the thickness of first resin layer 3a in the form of a film is highly accurate. Therefore, the thickness of first resin layer 3a can be managed with high accuracy. Even if the thickness of semiconductor chip 5 is small, the thickness of first resin layer 3a can be managed by selecting an optimum film thickness depending on the thickness and size of semiconductor chip 5 as well as the amount of resin forced out by the displacement of semiconductor chip 5 into first resin layer 3a so that first resin layer 3a will not reach the surface of semiconductor chip 5 displaced into first resin layer 3a. According to the present embodiment, therefore, the resin that holds semiconductor chip 5 is easily prevented from sticking to the mounting tool by a simple process of managing the thickness of first resin layer 3a. As a consequence, the size of the mounting tool does not need to be smaller than semiconductor chip 5 to prevent the resin from sticking to the mounting tool. As the mounting tool which is greater in size than semiconductor chip 5 can be used, the mounting tool does not apply local stresses to semiconductor chip 5 which is thin, and semiconductor chip 5 does not tend to be damaged when semiconductor chip 5 is displaced into first resin layer 3a. Since the qualities that are required of first resin layer 3a can be determined with respect to second resin layer 3b, a wide choice of resin types that can be used as first resin layer 3a is available.

In the above description, the properties of first resin layer 3a and second resin layer 3b of wiring board 2 have been described such that the elastic modulus of second resin layer 3b at the melting point of first resin layer 3a is 1 GPa or higher. In the actual manufacturing process, however, in order to reliably melt the region of first resin layer 3a on which semiconductor chip 5 is mounted when semiconductor chip 5 is displaced into first resin layer 3a, the temperature of first resin layer 3a may be higher than the melting point of first resin layer 3a in consideration of the heat radiation from wiring board 2 itself and semiconductor chip 5 and variations of temperature control of the heating device. If second resin layer 3b is made of a thermoplastic resin, then the temperature T° C. of first resin layer 3a should preferably be managed in a temperature range of T_{M}° C.≦T≦T_{M}+10° C. where T_{M}° C. represents the melting point of first resin layer 3a so that second resin layer 3b will not be softened by the heat of first resin layer 3a. It is thus desirable to establish the relationship between first resin layer 3a and second resin layer 3b such that the elastic modulus of second resin layer 3b is 1 GPa or more greater than the elastic modulus of first resin layer 3a in the temperature range of T_{M}° C.≦T≦T_{M}+10° C. Therefore, any sinking of interconnections 4 due to semiconductor chip 5 as it is mounted can be more effectively prevented from occurring.

It has been described above that semiconductor chip 5 is displaced into first resin layer 3a when first resin layer 3a is being melted with heat. However, if first resin layer 3a is made of a material which is softened to allow bumps 6 to penetrate first resin layer 3a at a temperature lower than the melting point thereof, then semiconductor chip 5 can be displaced into first resin layer 3a at a temperature lower than the melting point. At this time, the elastic modulus of first resin layer 3a needs to be 1 GPa or greater when semiconductor chip 5 is being pressed against first resin layer 3a.

For further increased reliability, the interconnections themselves should preferably be increased in rigidity to make interconnections 4 less liable to sink into second resin layer 3b and to reduce the load to press semiconductor chip 5 for thereby reducing any deformation of second resin layer 3b. The rigidity of interconnections 4 can specifically be increased by adding a highly rigid metal, such as Ni, to the material of interconnection 4 or by increasing the thickness of interconnections 4. The increased rigidity of interconnections 4 is effective to increase the contact pressure between bumps 6 and interconnections 4. For reducing the load to press semiconductor chip 5, it is important to do this without a reduction the contact pressure between bumps 6 and interconnections 4. In order to achieve a higher contact pressure under the same load, the diameter of bumps 6 may be reduced, or bumps 6 may be made of a low-rigidity material so that bumps 6 can be easily deformed.

The present embodiment is applicable to the mounting of not only general semiconductor chip 5, but also to the mounting of a semiconductor chip which is mounted on the circuit surface and is connected by secondary interconnections, a packaged electric component such as a wafer-level CSP, or a passive electronic component, insofar as they have protrusive electrodes on one surface thereof.

Various electronic devices, which incorporates the basic structure described above, according to other embodiments of the present invention will be described below. In the examples described below, the mutual relationship of properties of first resin layer 3a and second resin layer 3b, applicable materials thereof, and applicable electronic components are the same as those described above with respect to the above embodiment, unless otherwise specified.

FIG. 7 shows an electronic device incorporating wiring board 2 wherein first resin layer 3a with second interconnections 4a disposed in an electrically conductive pattern thereon is stacked on second resin layer 3b with interconnections 4 disposed thereon. Semiconductor chip 5 is joined to wiring board 2 when it is displaced into first resin layer 3a and bumps 6 pierce first resin layer 3a and are held in contact with interconnections 4. Wiring board 2 may be manufactured by patterning interconnections 4 on second resin layer 3b, thereafter stacking a copper-clad insulating resin layer with a copper foil disposed on one surface thereof, and pattering the copper foil to form first resin layer 3a with interconnections 4a disposed thereon. Interconnections 4 can be patterned by a subtractive process, an additive process, or a semi-additive process which is generally used to manufacture wiring boards. Though a build-up process is employed to successively stack the layers, a general manufacturing process such as a process of stacking the layers together after interconnections 4, 4a are individually formed on resin layers 3a, 3b is available to wiring boards.

FIG. 8 shows a BGA-type semiconductor package wherein an electrically conductive pattern on first resin layer 3a is formed as ground pattern 7, and ground pattern 7 is connected to ground 7a as an inner layer of the wiring board by via holes 8. Solder resists 9 are disposed on both surfaces of the wiring board. A plurality of pads are disposed on the lower surface of second resin layer 3b (the surface remote from first resin layer 3a), and they connected to interconnections 4 and ground 7a on second resin layer 3b by via holes 8a. Solder balls 31 are disposed on the pads. As the electrically conductive pattern on the face side is formed as ground pattern 7, it provides a noise shield effect.

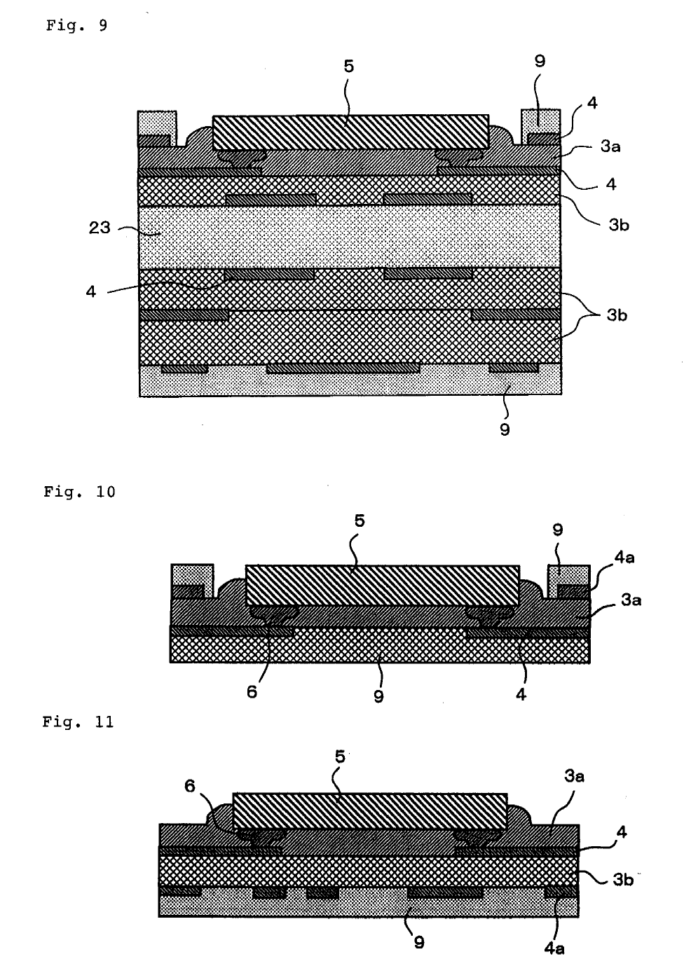

FIG. 9 is a cross-sectional view showing an example wherein wiring board 2 shown in FIG. 7 is incorporated in a board having a multiplicity of interconnection layers. In this example, interconnections 4 and insulating layers are alternately stacked on both surfaces of core layer 23 to provide a multilayer wiring board. The insulating layers include a surface layer that is constructed as first resin layer 3a made of a thermoplastic resin and other layers constructed as second resin layers 3b. First resin layer 3a has a thickness ranging from 30 to 100 μm.

Core layer 23 may comprise a glass epoxy substrate, and each of second resin layers 3b may be made of a built-up insulating resin. The resin of any of core layer 23 and second resin layers 3b may be a thermosetting resin. If first resin layer 3a is made of thermoplastic resin, the other layers are made of a thermosetting resin, and the materials of first resin layer 3a and second resin layer 3b are selected such that the elastic modulus of second resin layer 3b is 1 GPa at the melting point of first resin layer 3a, then though first resin layer 3a is sufficiently softened and deformed to a large extent, second resin layers 3b and core layer 23 are softened and deformed to a very small extent. Accordingly, the same procedure as described above can be employed to mount semiconductor chip 5 on the multilayer wiring board.

In the illustrated example, layers other than first resin layer 3a which is pierced by the bumps of semiconductor chip 5 are made of a thermosetting resin. However, all the insulating layers may be made of a thermoplastic resin. In such a case, first resin layer 3a is made of a material whose melting point is lower than the melting point of second resin layer 3b such that the elastic modulus of second resin layer 3b is 1 GPa or greater at the melting point of first resin layer 3a. To displace semiconductor chip 5 into first resin layer 3a, the wiring board may be heated to a temperature equal to or higher than the melting point of first resin layer 3a insofar as the elastic modulus of second resin layer 3b is 1 GPa or greater. In this manner, semiconductor chip 5 can be displaced into first resin layer 3a when only first resin layer 3a is being melted. If all the insulating layers are made of a thermoplastic resin, then the wiring board can be constructed as a packaged laminated board which is cost advantageous.

FIG. 10 is a cross-sectional view of an electronic device employing a wiring board which includes first resin layer 3a made of a thermoplastic resin as a core layer. The wiring board is fabricated using a copper-clad board which comprises first resin layer 3a having copper foils disposed on both surfaces thereof. The wiring board, which is manufactured by a general manufacturing process, includes interconnections 4, 4a formed by patterning the copper foils according to a subtractive process and solder resists 9 applied to both surface layers. As described above, semiconductor chip 5 is mounted on the wiring board by being displaced into first resin layer 3a which is softened or melted and by causing bumps 6 to pierce first resin layer 3a to come into contact with interconnections 4. A layer of solder resist 9 beneath first resin layer 3a is required to have an elastic modulus of 1 GPa or higher at the melting point of first resin layer 3a. Stated otherwise, the second resin layer functions as solder resist 9 in the present example.

FIG. 11 is a cross-sectional view of an electronic device employing a wiring board which includes second resin layer 3b having interconnections 4, 4a on its face and reverse surfaces as a core layer. Solder resist 9 is disposed on the reverse surface of second resin layer 3b, and first resin layer 3a made of a thermoplastic resin, which functions as a solder resist, is disposed on the face surface thereof. Semiconductor chip 5 is mounted on the wiring board by bringing bumps 6 into contact with interconnections 4 according to the same procedure as described above. According to the present example, first resin layer 3a doubles as a solder resist and a sealing resin for semiconductor chip 5. Since first resin layer 3a functions as a solder resist, interconnections 4 remain insulated from outside of the electronic device. If openings are formed in solder resist 9 on the reverse surface of the wiring board at positions corresponding to interconnections 4 and if terminals are disposed in the openings for external connections, then the electronic device can be used as a semiconductor package.

FIG. 12 shows an electronic device employing the wiring board of a multilayer structure which comprises first resin layer 3a, second resin layers 3b, and third resin layer 3c. In the example shown in FIG. 12, the wiring board has five insulating layers. Three layers on the reverse surface are formed as second resin layers 3b, and first resin layer 3a is stacked adjacent to second resin layer 3b near the face surface. Third resin layer 3c is stacked adjacent to first resin layer 3a. Interconnections 4 are disposed between resin layers 3a through 3c, and semiconductor chips 5a, 5b are held respectively in first resin layer 3a and third resin layer 3c. First resin layer 3a and third resin layer 3c may be made of a thermoplastic resin, prepreg, or the like.

The electronic device according to the present example can be manufactured according to the following procedure: First, first resin layer 3a is formed on second resin layer 3b, and then semiconductor chip 5a is pressed into first resin layer 3a according to the above process, after which first resin layer 3a is cured. The mounting of one semiconductor chip 5a is now completed. Then, third resin layer 3c is formed on semiconductor chip 5a, and semiconductor chip 5b is pressed into third resin layer 3c according to the above process, after which third resin layer 3c is cured.

The relationship needs to be established between first resin layer 3a, second resin layers 3b, and third resin layer 3c: With respect to first resin layer 3a and second resin layer 3b which are disposed adjacent to each other in the stacking direction, the elastic modulus of second resin layer 3b at the melting point of first resin layer 3a is 1 GPa or higher as described above. With respect to first resin layer 3a and third resin layer 3c, the elastic modulus of first resin layer 3a at the melting point of third resin layer 3c is 1 GPa or higher. If the materials of first resin layer 3a, second resin layers 3b, and third resin layer 3c are selected to satisfy the above relationship, then sinking of interconnections 4 into the resin layer is prevented from occurring and the electronic device where the wiring board and semiconductor 5a, 5b are connected to each other highly reliably is produced according the arrangement shown in FIG. 12.

In the present example, single third resin layer 3c is stacked on first resin layer 3a. Two or more third resin layers 3c may be employed, and semiconductor chips may be displaced respectively into those third resin layers 3c. In such a case, third resin layers 3c that are adjacent to each other in the stacking direction are related to each other such that the materials of third resin layers 3c are selected for a lower layer so that it will have an elastic modulus of 1 GPa or higher at the melting point of an upper layer.

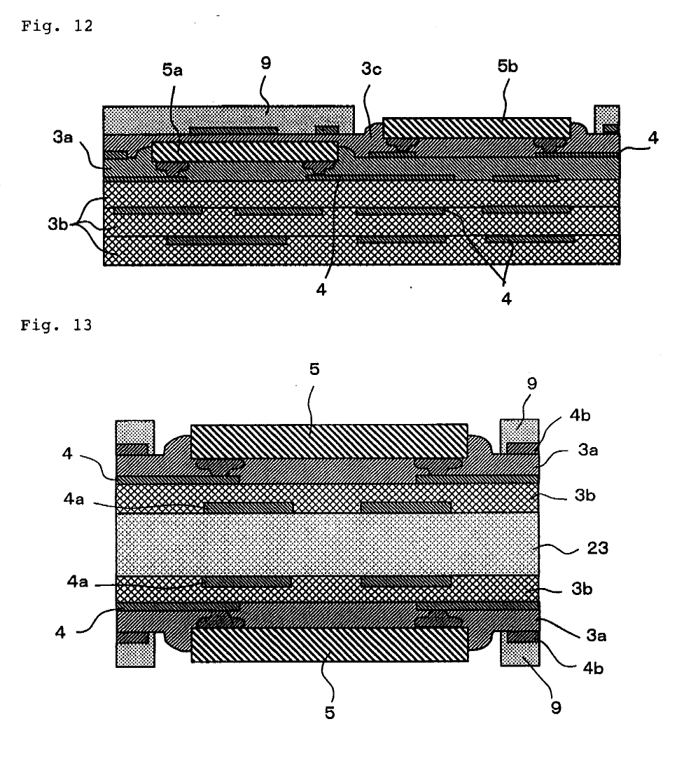

FIG. 13 is a cross-sectional view of an electronic device wherein semiconductor chips 5 are mounted on a multilayer wiring board. The wiring board according to the present example includes core layer 23 having a plurality of insulating layers stacked on both surfaces thereof with interconnections 4, 4a, 4b interposed therebetween. On the face surface of core layer 23, these insulating layers include second resin layer 3b disposed on core layer 23 and two first resin layers 3a disposed on second resin layer 3b. On the reverse surface of core layer 23, these insulating layers include two second resin layers 3b. Solder resist 9 is disposed on the face and reverse surfaces of the wiring board. Semiconductor chip 5 has bumps 6 piercing two first resin layers 3a and connected to interconnections 4. Since semiconductor chip 5 is displaced into a plurality of first resin layers 3a, interconnections 4b may be added between these layers. Therefore, the electronic device has increased degrees of freedom as to structural details and interconnections.

According to the present example, unlike the example shown in FIG. 12, first resin layers 3a may be made of one material or different materials provided that second resin layers 3b have an elastic modulus of 1 GPa or higher at the melting point of each of first resin layers 3a. The number of first resin layers 3a is not limited to two, but may be three or more.

Interconnections 4b between first resin layers 3a may be formed as ground. For example, if another semiconductor chip (not shown) is mounted on semiconductor chip 5 shown in FIG. 13 and interconnections 4a are used as signal lines, then interconnections 4b in a lower layer may be formed as ground to provide a noise shield effect mutually between the semiconductor chips for thereby preventing the electronic device from malfunctioning and allowing the electronic device to operate at a high speed.

FIG. 14 shows an electronic device employing a wiring board wherein second resin layers 4b are stacked on the face and reverse surfaces of core layer 23 having interconnections 4a interposed therebetween, and first resin layers 3a are stacked on the surfaces of second resin layers 4b with interconnections 4 interposed therebetween. Two semiconductor chips 5 are displaced into and mounted in respective first resin layers 3a on the face and reverse surfaces with their bumps 6 piercing first resin layers 3a and connected to interconnections 4. Semiconductor chips 5 face away from each other with their bumps 6 facing each other. If first resin layers 3a are disposed on the face and reverse surfaces of the wiring board, then it is possible to manufacture a device having semiconductor chips mounted on both surfaces thereof. Interconnections 4b on the surfaces of respective first resin layers 3a are covered with solder resists 9.

The electronic device according to the present example may be manufactured as follows: First, one of semiconductor chips 5 is mounted on the wiring board in the manner described above. Then, the wiring board with semiconductor chip 5 mounted thereon is turned upside down, and the other semiconductor chip 5 is mounted on the surface of the wiring board which is remote from the surface on which semiconductor chip 5 has already been mounted. In the present example, two second resin layers 3b and core layer 23 are interposed between two first resin layers 3a of the wiring board, so that heat is less liable to be transmitted between first resin layers 3a. As a result, when first resin layer 3a is heated to allow second semiconductor chip 5 to be displaced thereinto to mount second semiconductor chip 5 thereon, first resin layer 3a on which semiconductor chip 5 has already been mounted is not softened or melted, and semiconductor chip 5 that has already been mounted remains connected to interconnections 4.

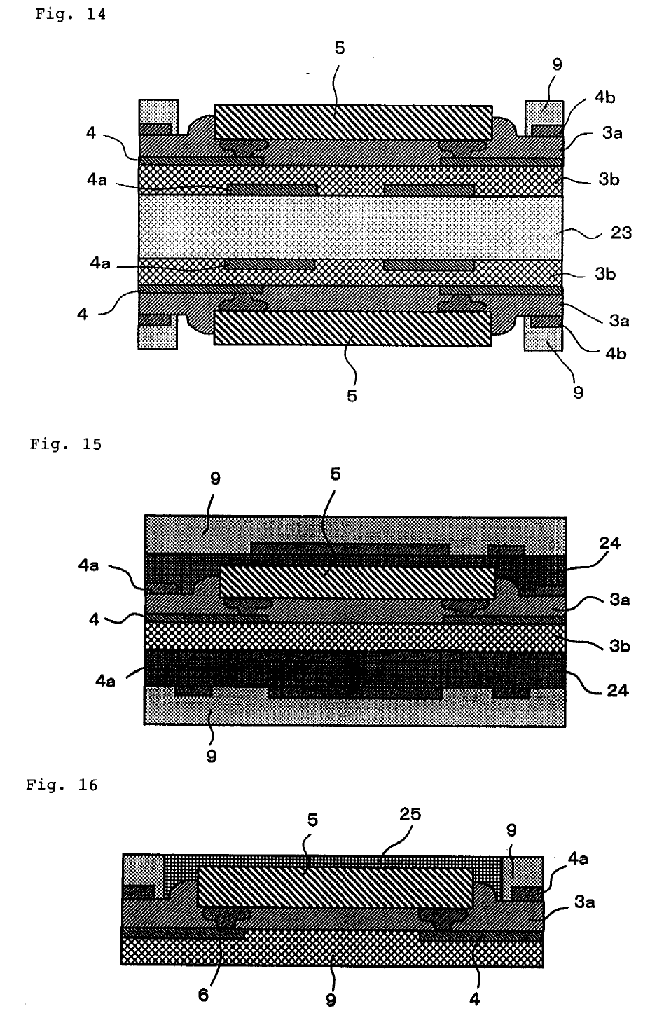

FIG. 15 shows an example wherein additional insulating layers 24 are stacked on the face and reverse surfaces, with interconnections 4a interposed therebetween, of the structure in which semiconductor chip 5 is displaced into first resin layer 3a disposed on second resin layer 3b with interconnections 4 interposed therebetween, thereby connecting interconnections 4 and bumps 6 to each other, as shown in FIG. 1. Additional insulating layer 24 may be disposed on only the face surface or only the reverse surface. The number of additional insulating layers 24 is optional depending on the characteristics required of the electronic device. If additional insulating layer 24 is disposed on the face surface, semiconductor chip 5 is fully embedded in the wiring board. Additional insulating layers 24 may be made of a thermoplastic resin, prepreg, or the like. The thickness of each of additional insulating layers 24 ranges from about 30 to 100 μm. As shown in FIG. 15, interconnections and solder resists may be disposed on the face surface and the reverse surface. For manufacturing the device shown in FIG. 15, semiconductor chip 5 is mounted on first resin layer 3a after first resin layer 3a is formed and before additional insulating layer 24 is formed on first resin layer 3a.

Since the device according to the present example can be manufactured at a low cost as described above, the cost of the final product is made lower than if semiconductor chip 5 is mounted on a general wiring board, and a chip component can be mounted with high density owing to incorporate semiconductor chip 5 therein, with the result that a product incorporating the present device can be reduced in size. As semiconductor chip 5 is incorporated in the electronic device, interconnections 4, 4a are formed as inner layers, and via holes and ancillary structures for positioning the interconnections as the inner layers are minimized. Consequently, the overall length of the interconnections is shortened.

During use of the above structure being employed, when the device undergoes external stresses due to a drop impact, vibrations, or a temperature cycle, the external stresses are prevented from concentrating on the end face of semiconductor chip 5. Therefore, the reliability of the joint between semiconductor chip 5 and the wiring board is increased, and the electronic device can find a wider range of applications. This holds true for semiconductor chip 5a of two semiconductor chips 5a, 5b, incorporated in the wiring board, of the structure shown in FIG. 12.

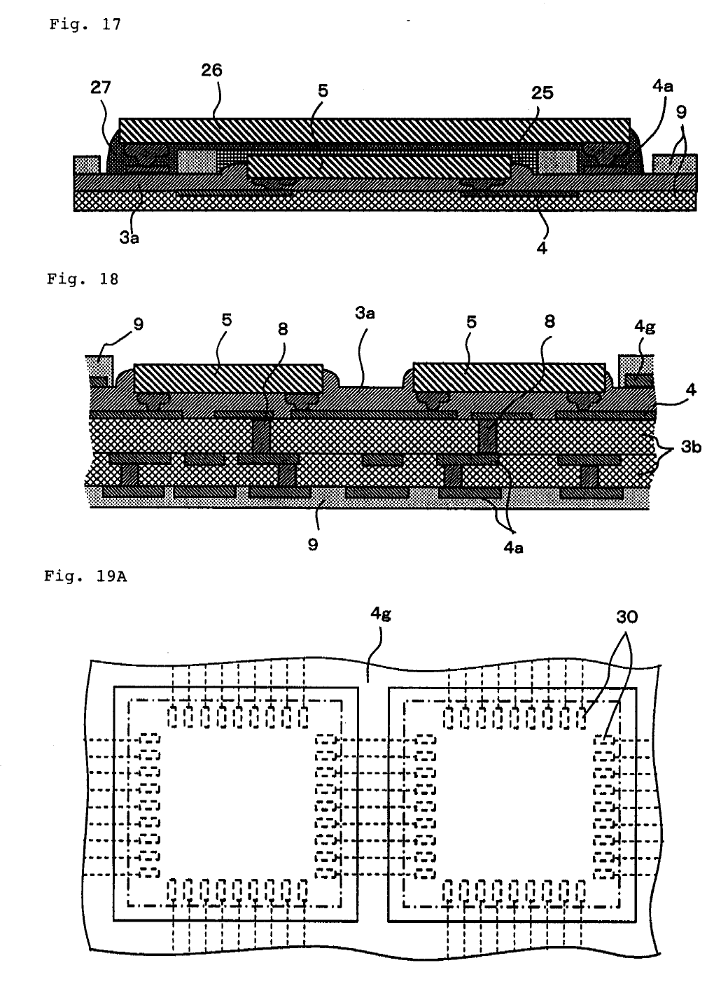

FIG. 16 shows a device wherein the region of the structure shown in FIG. 10 where semiconductor chip 5 is exposed is sealed by coating resin 25 which is an additional insulating layer. Other structural details wherein interconnections 4, 4a are disposed on both surfaces of first resin layer 3a serving as a core layer and covered with respective solder resists 9, and one of solder resists 9 which is stacked with interconnections 4 connected to bumps 6 being interposed therebetween functions as a second resin layer, and wherein semiconductor chip 5 is retained in first resin layer 3a and mounted in place with bumps 6a piercing first resin layer 3a and connected to the interconnections, are identical to those of the structure shown in FIG. 10. Coating resin 25 may be formed by a dispenser or a screen printing process or the like. Coating resin 25 reinforces the upper surface of semiconductor chip 5 and makes the device surface flat. The present example offers the same advantages as the example shown in FIG. 15 because of incorporated semiconductor chip 5.

FIG. 17 shows a device that have the structure shown in FIG. 16 wherein semiconductor chip 5 is sealed by coating resin 25 and then another semiconductor chip 26 is superposed on the structure. Another semiconductor chip 26 is mounted on first resin layer 3a at a position overlapping semiconductor chip 5 sealed by coating resin 25, and is connected to interconnections 4a on first resin layer 3a of the wiring board. The gap between the other semiconductor chip 26 and the wiring board is filled with underfill resin 27. Semiconductor chip 5 is mounted on the wiring board according to the process described above. The other semiconductor chip 26 may be mounted on first resin layer 3a according to a flip-chip pressure bonding process of the related art. For mounting the other semiconductor chip 26 in place, underfill resin 27 should desirably be a resin which is cured at a temperature lower than the melting point of first resin layer 3a. Alternatively, a solder fusing process capable of mounting a semiconductor chip under a low load is also applicable. Generally, however, the other semiconductor chip 26 is often mounted in place by reflow soldering. To prevent the joint of semiconductor chip 5 from being broken when semiconductor chip 26 is mounted in place, a noncrystalline resin which is rigid at a relatively high temperature of 220° C., which is the melting point of lead-free solder, or a composite material of a noncrystalline resin and a crystalline resin are effective for use as the material of first resin layer 3a.

In the process of mounting the other semiconductor chip 26, concavities and convexities beneath semiconductor chip 26 affect the flowability of underfill resin 27 and lead to the generation of voids. Coating resin 25 covering semiconductor chip 5 is effective to reduce concavities and convexities between two semiconductor chips 5, 26, thereby allowing the gap to be effectively filled with underfill resin 27.

FIG. 18 is a cross-sectional view of an example employing a wiring board based on the structure shown in FIG. 8, wherein two additional insulating layers 24 are stacked on first resin layer 3a having interconnections 4a interposed therebetween around the regions where semiconductor chips 5 are mounted. The wiring board comprises second resin layers 3b, first resin layer 3a stacked on second resin layers 3b with interconnections 4 interposed therebetween, and additional insulating layers 24 made of a resin material, for example, stacked on first resin layer 3a with interconnections 4 interposed therebetween. Additional insulating layers 24 have openings defined in the regions where semiconductor chips 5 are mounted. The openings in additional insulating layers 24 may be formed by a boring process such as punching or the like in a desired insulating layer (each insulating layer 24) if the wiring board is fabricated by a build-up process. Semiconductor chips 5 are inserted in the openings in additional insulating layers 24, and mounted on first resin layer 3a in the same manner as described above.

The wiring board may be manufactured according to an additive process by patterning interconnections 4 on second resin layers 3b, thereafter stacking first resin layer 3a with a copper foil on one surface thereof, patterning the copper foil on first resin layer 3a to form interconnections 4a, thereafter stacking additional insulating layers 24 with a copper foil on one surface thereof, and patterning the copper foil on additional insulating layers 24 to form interconnections 4a. Alternatively, the wiring board may be manufactured according to a general process of manufacturing multilayer wiring boards, such as a process of forming interconnections 4, 4a on resin layers 3a, 3b and additional insulating layers 24 and stacking them altogether. However, interconnections 4, 4a may not necessarily be formed on first resin layer 3a and additional insulating layers 24. The number of resin layers 3a, 3b and additional insulating layers 24 are optional depending on characteristics, performance, etc. required of the device. For example, a plurality of additional insulating layers 24 may be provided as shown in FIG. 18. The present example has essentially the same mechanical characteristics as those of the device wherein semiconductor chip 5 is incorporated in the wiring board. However, since semiconductor chips 5 have their surfaces exposed through the openings in the wiring board, heat sinks (not shown) may be attached to the surfaces of semiconductor chips 5 to increase the heat radiation of semiconductor chips 5.

In the present example, the wiring board with the openings is used, and semiconductor chips 5 are mounted in the openings. Therefore, the manufacturing process is made simpler than the manufacturing process for the chip-incorporated device shown in FIG. 15 because semiconductor chips 5 can be mounted in place after the process of manufacturing the wiring board is completed, though the device according to the present example offers substantially the same advantages as those of the chip-incorporated device. In the example shown in FIG. 18, pads to which terminals for external connection are connected are disposed on the reverse surface of the wiring board. With terminals provided on the pads, the device can be used as a semiconductor package.

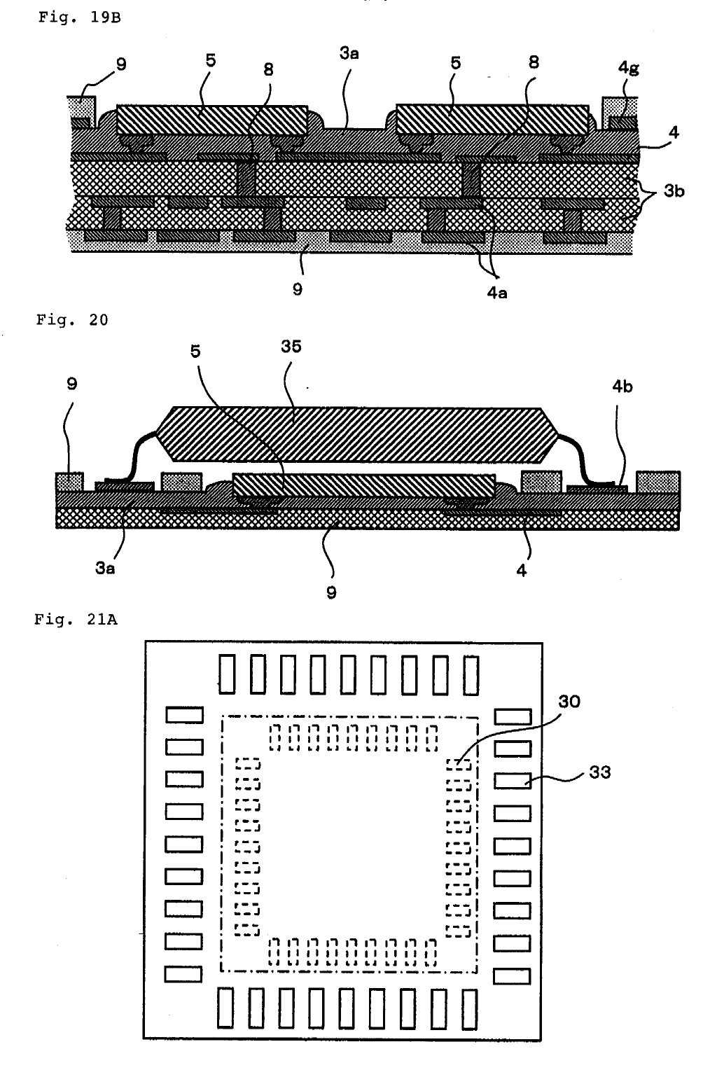

FIGS. 19A and 19B show an electronic device wherein a plurality of semiconductor chips 5 are mounted on a single first resin layer 3a. FIG. 19A is a plan view of a wiring board with no semiconductor chips 5 mounted thereon, and FIG. 19B is a cross-sectional view of the electronic device. In FIG. 19A, positions where semiconductor chips 5 are mounted in place are indicated by the dot-and-dash lines.

The device according to the present example is an application of the structure shown in FIG. 8. An electrically conductive pattern on the surface layer of first resin layer 3a is constructed as ground pattern 4g. Two semiconductor chips 5 are mounted on the wiring board. Ground pattern 4g is disposed entirely outside of the two regions where semiconductor chips 5 are mounted in place. Two second resin layers 3b are stacked below first resin layer 3a with interconnections 4, 4a interposed therebetween. The interlayer interconnections are connected to each other through via holes 8. Ground pattern 4g and interconnections 4a in the lowermost layer are covered with solder resist 9.

The bumps of semiconductor chips 5 are connected to pads 30 disposed on the tip ends of interconnections 4 between first resin layer 3a and second resin layers 3b. Interconnections 4 to which the bumps of semiconductor chips 5 are connected are connected to the bumps of adjacent semiconductor chips 5 or connected to interconnections 4a in the lower layer through via holes 8.

In the present example, the bumps of semiconductor chips 5 are connected to interconnections 4 in the inner layer in the wiring board wherein the electrically conductive pattern on the surface layer is constructed as ground pattern 4g. Since interconnections 4 connected to the bumps of semiconductor chips 5 do not need to be connected to other layers through via holes 8, the number of via holes 8 can be reduced and the device can be packaged having high density chips.

The above features will be described in specific details below. Two or more semiconductor chips mounted on a board are wired, and a ground pattern as a noise shield is placed entirely over the surface layer of the board. The path of the signal lines from one of the semiconductor chips to the other will be analyzed below. Generally, signal lines connected to a semiconductor chip are connected to ½ to ⅓ of all terminals thereof, and other terminals thereof are power and ground terminals. If it is assumed that a semiconductor chip has 100 external terminals and 50 of the terminals are connected to signal lines, then in the structure of the related art wherein a semiconductor chip is mounted on the surface layer of a board, all the signal lines need to be connected to an inner layer through via holes and pass through a layer below a ground pattern on the surface layer to provide a noise shield, and thereafter need to be connected through other via holes from the inner layer to a semiconductor chip on the surface layer. Because 50 terminals are required for connection from the surface layer to the inner layer and 50 terminals are required for connection from the inner layer to the surface layer, a total of 100 via holes which are twice the number of signal lines are required. In the arrangement according to the present invention wherein a chip component is connected to interconnections in an inner layer, a plurality of chip components can be connected by direct wiring in one layer. Therefore, no via holes are required between the surface layer and the inner layer, and all 100 via holes between the surface layer and the inner layer are dispensed with.

According to the present example, since no via holes need to be formed around semiconductor chips 5 in the surface layer of the wiring board, the region which is not covered with ground pattern 4g can be minimized for an increased shield effect. For example, though it is ideal to provide ground pattern 4g in the entire region around semiconductor chips 5, a resin material actually rises around semiconductor chips 5 as semiconductor chips 5 are displaced into first resin layer 3a. In view of the rising resin material, the gap between the edges of semiconductor chips 5 and ground pattern 4g may be set to about 0.5 mm.

FIG. 20 is a cross-sectional view of an example wherein packaged electronic component 35 is mounted on first resin layer 3a in a position overlying semiconductor chip 5 embedded in the wiring board. The wiring board is the same as shown in FIG. 10 and includes solder resist 9 disposed on both surfaces of first resin layer 3a which has interconnections 4a, 4b on both surfaces. As described above, semiconductor chip 5 is mounted in place with its bumps piercing first resin layer 3 and connected to interconnections 4. Pads disposed on the ends of interconnections 4 disposed on first resin layer 3a are supplied with cream solder by a printing process. Electronic component 35 is surface-mounted by having its lead terminals positioned on the pads and connected thereto by reflow soldering.

In the present example, if first resin layer 3a is made of a thermoplastic resin, then it should desirably be a noncrystalline resin which keep rigid in at a relatively high temperature of 220° C., which is the melting point of lead-free solder, or a composite material of a noncrystalline resin and a crystalline resin, so that the joint of semiconductor chip 5 will not be damaged at a reflow temperature.

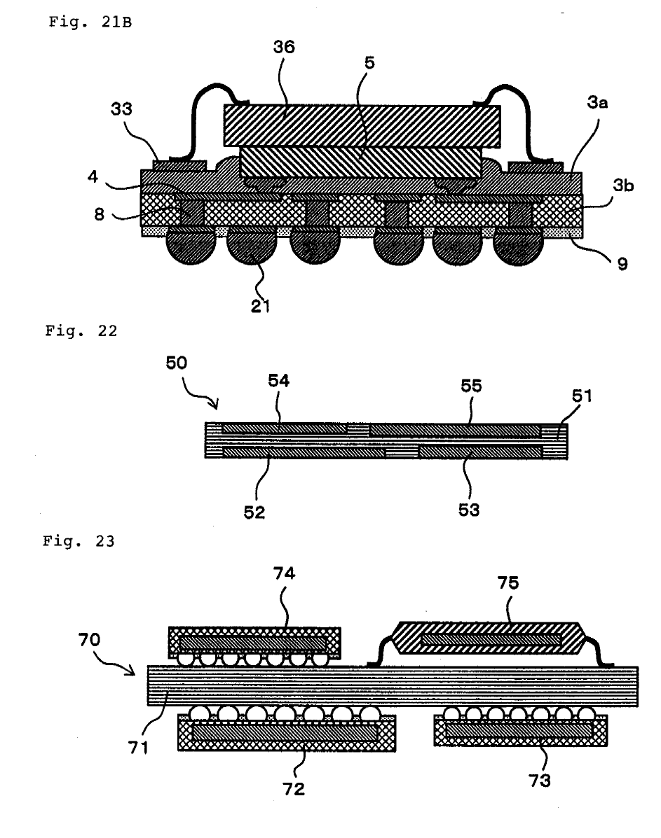

FIGS. 21A and 21B show an example wherein the BGA shown in FIGS. 28A and 28B is applied to the present invention. FIG. 21A is a plan view of a wiring board having no semiconductor chips 5, 36 mounted thereon, and FIG. 21B is a cross-sectional view of a semiconductor package wherein two semiconductor chips 5, 36 are mounted on the wiring board shown in FIG. 21A. In FIG. 21A, the position where semiconductor chip 5 is mounted is indicated by the dot-and-dash lines.

In the present example, the bumps of semiconductor chip 5 are connected to pads 30 in an inner layer on the ends of interconnections 4 on second resin layer 3b, and another semiconductor chip 36 is mounted face-up on semiconductor chip 5 with its circuit surface facing upwardly. On first resin layer 3a, pads 33 for connection to other semiconductor chip 36 are disposed around pads 30, and are connected to the electrodes (not shown) of the other semiconductor chip 36 by bonding wires 34. Solder balls 21 are disposed in a region that is on the reverse surface of the wiring board which is not covered with solder resist 9. In the present example, the bumps of semiconductor chip 5 are connected to the interconnections in the inner layer to offer the following advantages: On the surface layer of the wiring board, there is no need to provide via holes around semiconductor chip 5 for connecting the interconnections connected to semiconductor chip 5 to the inner layer of the wiring board. Therefore, the number of via holes is reduced. Because pads 33 for connection to the other semiconductor chip 36 are disposed closely to semiconductor chip 5, bonding wires 34 are shortened. According to the present embodiment, furthermore, the semiconductor package is packaged having high density chips, and the number of interconnection layers is reduced.

FIG. 22 is a schematic view of functional module 50 to which the present invention is applied, wherein semiconductor chips 52 through 55 are mounted on both surfaces of wiring board 51, and FIG. 23 is a schematic view of functional module 70 of the related art for comparison with functional module 50 shown in FIG. 22.

Functional module 70 shown in FIG. 23 is of a general structure wherein semiconductor packages 72 through 75 are mounted on both surfaces of wiring board 71. For use on a function module for mobile telephone, for example, semiconductor packages mainly have a planar size ranging from 5 to 15 mm on each of four sides and a mounted height ranging from 1.0 to 1.4 mm. Semiconductor packages 72 through 75 mounted on wiring board 71 have the following sizes: Semiconductor package 74 has a planar size of 7 mm×7 mm and a mounted height of 1.2 mm. Semiconductor package 75 has a planar size of 15 mm×15 mm and a mounted height of 1.5 mm. Semiconductor package 72 has a planar size of 10 mm×10 mm and a mounted height of 1.4 mm. Semiconductor package 73 has a planar size of 7 mm×7 mm and a mounted height of 1.2 mm. Wiring board 71 has 6 interconnection layers, a thickness of 0.8 mm, and a planar size of 28 mm×28 mm as it requires a mounting area of a package size+3 mm for each semiconductor package. Therefore, it is easily concluded that functional module 70 of the related art with semiconductor packages 72 through 75 mounted thereon have a planar size of 28 mm×28 mm and a thickness of about 3.6 mm.

It is assumed that functional module 50 shown in FIG. 22 includes an electronic device wherein semiconductor chips sealed in semiconductor packages 72 through 75 shown in FIG. 23 are directly mounted on wiring board 51 having at least first resin layer 3a and second resin layer 3b according to the process described above. It is also assumed that the size of semiconductor chips 52 through 55 is 70 percent of the size of semiconductor packages 72 through 75 shown in FIG. 23. As a result, semiconductor chips 52 through 55 have the following planar sizes: Semiconductor chip 54 has a planar size of 4.9 mm×4.9 mm. Semiconductor chip 55 has a planar size of 10.5 mm×10.5 mm. Semiconductor chip 52 has a planar size of 7 mm×7 mm. Semiconductor chip 53 has a planar size of 4.9 mm×4.9 mm. It is also assumed that each of semiconductor chips 52 through 55 has a thickness of 0.1 mm and is embedded in wiring board 51 to a depth which is one-half of the thickness. Each of semiconductor chips 52 through 55 has a mounted height of 0.05 mm. Wiring board 51 is expected to have a reduced number of four interconnection layers because the interconnections are directly connected to the inner layers according to the present invention. In this case, wiring board 51 has a thickness of 0.6 mm and a planar size of 17.4 mm×17.4 mm if a mounting area for each semiconductor chip is a chip size+1 mm.

Based on the above analysis, functional module 50 shown in FIG. 50 which has a planar size of 17.4 mm×17.4 mm and a thickness of 0.7 mm can perform the same functions as functional module 70 of the related art which includes semiconductor packages 72 through 75. According to the present example, based on the principles of the present invention, it is expected that the area of the module is reduced by 62% and the thickness thereof is reduced by 81%, resulting in a significant reduction in size and thickness.

The structure of the related art and the structure according to the present invention will now be compared with each other using the functional module with the semiconductor packages mounted thereon and the functional modules with semiconductor chips mounted directly thereon.

Reasons for such comparison are as follows: According to the related art, the diameter of the land of a via hole is almost 200 μm and the layout pitch of via holes is almost 300 μm in the wiring board. If semiconductor chips, particularly multipin semiconductor chips having more than 300 pins, are to be directly mounted on the wiring board, then a number of via holes are required. Therefore, interconnections from semiconductor chips need to be extended to a range where via holes can be placed, so that efforts to reduce the size of functional modules with semiconductor packages mounted thereon are limited. Heretofore, for better handleability, it has been the general practice to construct functional modules with semiconductor packages mounted thereon, rather than functional modules with semiconductor chips directly mounted thereon.

According to the present invention, since the bumps of a semiconductor chips are directly connected to interconnections in an inner layer of a wiring board, the number of via holes is greatly reduced. Consequently, the size of electronic device with semiconductor chips directly mounted on a wiring board is drastically reduced. Since the number of via holes is greatly reduced, the interconnections are made shorter than if semiconductor chips were mounted on the surface of the wiring board as is the case with the related art. The shorter interconnections are effective to reduce degradation of signal quality due to attenuation of electric signals and noise picked up from the interconnections.

The present invention makes it possible to realize a small-size, high-density semiconductor package or functional module having excellent electric characteristics, to reduce the size and thickness of an electronic device, and to provide inexpensive and attractive products.

The functional module may be in the form of a variety of modules for use in mobile units such as mobile telephone sets, such as a camera module, a liquid crystal module, an RF module, a wireless LAN module, a Bluetooth (registered trademark) module, a system-in-package module comprising a plurality of chips assembled into one package, etc.

The electronic device according to the present invention is not limited to any particular type, but may be all kinds of electronic devices, e.g., semiconductor chips including a CPU, a logic circuit, a memory, etc. If individual semiconductor chips are constructed as semiconductor packages according to the present invention, they can be realized as small, low-profile packages which can be manufactured with a higher yield, are of higher reliability, and are lower in cost than semiconductor packages of the related art.

If an electronic device, a functional module, or a semiconductor package according to the present invention is incorporated in an electric apparatus, then mobile devices including mobile telephone sets, digital still cameras, PDAs (Personal Digital Assistants), notebook personal computers, etc. can further be reduced in size and thickness and have their added values increased. Furthermore, if the present invention is applied to high-end products such as computers, servers, etc., then since they can have excellent characteristics and can be packaged with high density chips, they are expected to have increased performance.

1. An electronic device comprising:
a wiring board including a first resin layer and a second resin layer which are stacked one on the other with interconnections interposed therebetween; and
at least one chip component having protrusive electrodes disposed on one surface thereof;
said chip component being displaced into said first resin layer and connected to said interconnections with said protrusive electrodes being held in contact with said interconnections;
said first resin layer containing at least one thermoplastic resin, and said second resin layer having an elastic modulus of 1 GPa or higher at the melting point of said first resin layer.

2. The electronic device according to claim 1, wherein said first resin layer is made of a noncrystalline resin or a composite material of a crystalline resin and a noncrystalline resin.

3. The electronic device according to claim 1, wherein said first resin layer has a linear expansion coefficient in a range between the linear expansion coefficient of said chip component and the linear expansion coefficient of said second resin layer.

4. The electronic device according to claim 1, wherein said first resin layer has a linear expansion coefficient that is closer to the linear expansion coefficient of said chip component than an intermediate value between the linear expansion coefficient of said chip component and the linear expansion coefficient of said second resin layer.

5. The electronic device according to claim 1, wherein said first resin layer contains a filler.

6. The electronic device according to claim 1, further comprising a conductor pattern disposed on a surface of said first resin layer which is remote from the surface thereof on which the interconnections held in contact with said protrusive electrodes are disposed.

7. The electronic device according to claim 6, wherein said conductor pattern comprises interconnections other than said interconnections.

8. The electronic device according to claim 6, wherein said conductor pattern comprises a ground pattern.

9. The electronic device according to claim 1, wherein said wiring board includes a third resin layer stacked on said first resin layer with interconnections other than said interconnections being interposed therebetween, said third resin layer containing a thermoplastic resin;
said first resin layer having an elastic modulus of 1 GPa or higher at the melting point of said second resin layer; and
wherein a chip component other than said chip component and having protrusive electrodes disposed on one surface thereof is displaced into said third resin layer and is connected to the other interconnections with said protrusive electrodes being held in contact with said other interconnections.

10. The electronic device according to claim 1, wherein said wiring board includes a plurality of said first resin layers.

11. The electronic device according to claim 10, wherein said first resin layers are stacked in contact with each other, said chip component being held by said first resin layers with said protrusive electrodes piercing said first resin layers.

12. The electronic device according to claim 10, wherein two of said first resin layers are disposed on the face and reverse surfaces, respectively, of said wiring board, said chip component being held by each of said first resin layers.

13. The electronic device according to claim 1, further comprising an additional insulating layer covering said chip component.

14. The electronic device according to claim 13, wherein said insulating layer comprises a coating layer disposed on a surface of said wiring board.

15. The electronic device according to claim 1, further comprising at least one insulating layer disposed on said first resin layer and having an opening defined in a region in which said chip component is mounted.

16. The electronic device according to claim 15, wherein a plurality of said insulating layers each have said opening, said insulating layers being stacked with interconnections other than said interconnections being interposed therebetween.

17. The electronic device according to claim 1, further comprising an electronic component mounted in a position overlying the chip component held by said first resin layer.

18. The electronic device according to claim 17, wherein said electronic component comprises a chip component or a component with leads, said electronic component being mounted on said first resin layer and connected to interconnections disposed on said first resin layer.

19. The electronic device according to claim 17, wherein said electronic component comprises a chip component and has terminals disposed on a surface thereof, said surface facing away from the chip component held by said first resin layer, said terminals being connected by bonding wires to electrode pads disposed on said first resin layer.

20. The electronic device according to claim 1, wherein a plurality of said chip components are held by said first resin layer and are connected to each other by a portion of said interconnections between said first resin layer and said second resin layer.

21. A functional module comprising an electronic device according to claim 1.

22. An electronic apparatus comprising a functional module according to claim 21.

23. A semiconductor package comprising an electronic device according to claim 1, wherein said chip component comprises a semiconductor chip and has external connection terminals for making an electric connection to a device other than said electronic device.

24. An electronic apparatus comprising a semiconductor package according to claim 23.

25. A method of manufacturing an electronic device having a chip component mounted on a wiring board, comprising the steps of:
preparing a chip component with protrusive electrodes disposed on one surface thereof and a wiring board including a first resin layer and a second resin layer which are stacked one on the other with interconnections interposed therebetween, said first resin layer containing at least one thermoplastic resin, and said second resin layer having an elastic modulus of 1 GPa or higher at the melting point of said first resin layer;
heating a region of said first resin layer in which said chip component is mounted at a temperature equal to or higher than the melting point of said first resin layer;
pressing said chip component into said first resin layer in the heated region of said first resin layer while the surface with the protrusive electrodes faces said first resin layer;
bringing the protrusive electrode of said chip component into contact with said interconnections by piercing said first resin layer; and
holding said protrusive electrodes and said interconnections in contact with each other until said first resin layer is cured.

26. The method of manufacturing an electronic device according to claim 25, wherein said step of heating a region of said first resin layer in which said chip component is mounted includes the step of heating said chip component.

27. The method of manufacturing an electronic device according to claim 25, further comprising the step of, after the step of preparing said chip component and said wiring board, performing a plasma process on or applying ultraviolet rays to the region of said first resin layer in which said chip component is mounted, wherein said chip component is pressed into said first resin layer after the step of performing a plasma process on or applying ultraviolet rays to the region of said first resin layer in which said chip component is mounted.

28. A wiring board for mounting thereon at least one chip component with protrusive electrodes disposed on one surface thereof, comprising:
a first resin layer;
a second resin layer stacked on said first resin layer with interconnections interposed therebetween, said protrusive electrodes of the chip component displaced into said first resin layer being held in contact with said interconnections;
said first resin layer containing at least one thermoplastic resin, and said second resin layer having an elastic modulus of 1 GPa or higher at the melting point of said first resin layer.

29. The wiring board according to claim 28, wherein said first resin layer is made of a noncrystalline resin or a composite material of a crystalline resin and a noncrystalline resin.

30. The wiring board according to claim 28, wherein said first resin layer has a linear expansion coefficient in a range between the linear expansion coefficient of said chip component and the linear expansion coefficient of said second resin layer.

31. The wiring board according to claim 30, wherein said first resin layer has a linear expansion coefficient that is closer to the linear expansion coefficient of said chip component than an intermediate value between the linear expansion coefficient of said chip component and the linear expansion coefficient of said second resin layer.

32. The wiring board according to claim 28, wherein said first resin layer contains a filler.

33. The wiring board according to claim 28, further comprising a conductor pattern disposed on a surface of said first resin layer which is remote from the surface thereof on which the interconnections held in contact with said protrusive electrodes are disposed.

34. The wiring board according to claim 33, wherein said conductor pattern comprises interconnections other than said interconnections.

35. The wiring board according to claim 28, further comprising a plurality of said first resin layers.

36. The wiring board according to claim 35, wherein said first resin layers are stacked in contact with each other.

37. The wiring board according to claim 36, wherein said first resin layers are stacked with interconnections other than said interconnections being interposed therebetween.

38. The wiring board according to claim 35, wherein two of said first resin layers are disposed on the face and reverse surfaces, respectively, of said wiring board.

39. The wiring board according to claim 28, further comprising at least one insulating layer disposed on said first resin layer and having an opening defined in a region in which said chip component is mounted.

40. The wiring board according to claim 39, wherein a plurality of said insulating layers each have said opening, said insulating layers being stacked with interconnections other than said interconnections being interposed therebetween.
